(19) United States
(12) Patent Application Publication
(10) Pub. No.: US 2024/0297593 A1
(43) Pub. Date: Sep. 5, 2024

(54) HALF-BRIDGE SWITCH ARRANGEMENT

(71) Applicant: SEG Automotive Germany GmbH, Stuttgart (DE)

(72) Inventors: Nima SAADAT, Stuttgart (DE); Eric PERTERMANN, Stuttgart (DE); Walter KUNZI, Stuttgart (DE); Mathis LURTZ, Stuttgart (DE); Xaver LAUFENBERG, Stuttgart (DE); Timm LOHMANN, Stuttgart (DE)

(21) Appl. No.: 18/588,862

(22) Filed: Feb. 27, 2024

(30) Foreign Application Priority Data
Mar. 3, 2023 (DE) 102023105341.8

(51) Int. Cl. H02M 7/00; H05K 7/20

(52) U.S. Cl. CPC H02M 7/003; H05K 7/209

(57) ABSTRACT

A half-bridge switch arrangement includes a high-side switch having a plurality of parallel-connected first semiconductor switching elements, a low-side switch having a plurality of parallel-connected second semiconductor switching elements, a positive busbar connected to a first terminal of each of the first semiconductor switching elements, a negative busbar connected to a second terminal of each of the second semiconductor switching elements, and a heat sink arranged between a first section of the positive busbar and a first section of the negative busbar, wherein an outer surface of each of the first semiconductor switching elements is in thermal contact with a surface of the first section of the positive busbar facing away from the heat sink, and wherein an outer surface of each of the second semiconductor switching elements is in thermal contact with a surface of the first section of the negative busbar facing away from the heat sink.

### CROSS-REFERENCE TO RELATED APPLICATIONS

This application claims priority to German Patent Application No. 102023105341.8 filed Mar. 3, 2023, hereby incorporated in its entirety.

### TECHNICAL FIELD

The present disclosure relates to a half-bridge switch arrangement.

### BACKGROUND

Half-bridge switch arrangements can be used in power converters, for example, as inverters for alternating conversion between DC and AC voltages. For example, such half-bridge switch arrangements can be used in power modules in (motor) vehicles to convert a voltage between a DC on-board power supply and an electrical machine that can be operated with multi-phase AC voltage.

Such half-bridge switch arrangements have one half-bridge per phase with one high-side switch and one low-side switch. Individual, discrete semiconductor switching elements can be used as high-side or low-side switches, for example individual transistors such as FETs, MOSFETs, IGBTs, etc., or a parallel circuit consisting of a large number of such discrete semiconductor switching elements can be used.

This type of parallel connection of discrete components as high-side switches or low-side switches enables high power scalability and high power or current levels to be achieved. However, this often results in a high DC link inductance and therefore a high total inductance of the commutation loop. It can also often prove difficult to cool such half-bridge switch arrangements sufficiently in order to keep temperatures at desired values at high currents and high switching frequencies.

### SUMMARY

The disclosure relates to a half-bridge switch arrangement. The half-bridge switch arrangement has a high-side switch comprising a plurality of parallel-connected, discrete first semiconductor switching elements and a low-side switch comprising a plurality of parallel-connected, discrete second semiconductor switching elements. The individual semiconductor switching elements can each be designed, for example, as a transistor, e.g. as FETs, MOSFETs, IGBTs, etc.

Furthermore, the half-bridge switch arrangement has a positive busbar (“B+ busbar”), to which a first terminal of each of the first semiconductor switching elements of the high-side switch, in particular in each case a drain terminal, is electrically connected, and a negative busbar (“B-busbar”), to which a second terminal of each of the second semiconductor switching elements of the low-side switch, in particular in each case a source terminal, is electrically connected. For example, the positive and negative busbars can each be made of copper.

The half-bridge switch arrangement also has a heat sink, which is suitably provided and set up for cooling the busbars and the semiconductor switching elements. For example, the heat sink can be fluid-cooled and have an inlet and outlet for a corresponding cooling fluid. The cooling fluid can comprise oil, water, air, etc.

The heat sink is arranged between a first section of the positive busbar and a first section of the negative busbar. In particular, the first sections can be plate-shaped, rectilinear or flat. For example, neighboring side surfaces of the heat sink can rest against these first sections. The heat sink is thus in thermal contact with the first sections so that the busbars can be cooled effectively. The first sections can be arranged or run parallel to each other.

An outer surface of the first semiconductor switching elements is in thermal contact with a surface of the first section of the positive busbar facing away from the heat sink. Similarly, an outer surface of the second semiconductor switching elements is in thermal contact with a surface of the first section of the negative busbar facing away from the heat sink. By these thermal contacts, heat generated by the semiconductor switching elements can be effectively transferred to the busbars and dissipated from them to the heat sink.

Advantageous embodiments are the subject-matter of the dependent claims and the following description.

The disclosure provides a half-bridge switch arrangement with a low intermediate circuit inductance and a low thermal impedance, which can be cooled effectively.

The disclosure provides an improved half-bridge switch arrangement with parallel connections of individual semiconductor switching elements as high-side and low-side switches.

By connecting discrete switching elements in parallel as high-side or low-side switches, a high scalability of the power can be achieved in particular. The number of semiconductor switching elements in the respective parallel circuit can be appropriately selected in order to achieve a desired power or a desired current. Furthermore, the overall cost of the circuit can be kept low by using discrete switching elements.

The use of parallel, discrete semiconductor switching elements can often lead to a high parasitic inductance, which can be critical at a high switching speed of WBG elements (wide-bandgap semiconductors), such as SiC or GaN. Such parasitic inductance can be reduced in the switch arrangement according to the disclosure.

The positive busbar and negative busbar are advantageously arranged close to each other, whereby inductive resistance can be reduced or kept low. In particular, a low DC link inductance and a low total inductance of the commutation loop can be achieved. Due to the short distances between the lines or terminals of the switching elements and the busbars, the commutation loop can be optimized. The busbars can, for example, be laminated busbars with very low inductance, which enable the half bridge to switch at very high speed.

By arranging the positive and negative busbars on the heat sink, the busbars can be cooled efficiently. In addition, the arrangement of the semiconductor switching elements on the busbars means that a low thermal impedance can be achieved and the heat released by the switching elements can be effectively dissipated to the heat sink. Although the positive and negative busbars are close to each other to influence the overall inductance of the commutation loop, busbars and switch elements can still be cooled effectively. In particular, the junction temperature of the switch elements can be kept at a desired value at high currents and high switching frequencies.

Instead of using printed circuit board layers to produce the positive and negative busbars, copper plates can be used, for example, which are easy to bend and shape and are cheaper than thick copper circuit board layers. Furthermore, the busbars can also be produced by welding onto a piece of metal such as copper, for example. The sizes and dimensions of the busbars can be chosen flexibly and freely and can be adapted to a given installation space, for example.

According to an embodiment, the half-bridge switch arrangement further comprises a printed circuit board, wherein the positive busbar and the negative busbar are electrically connected to the printed circuit board. In an embodiment, the positive busbar and the negative busbar are arranged on the printed circuit board such that the first section of the positive busbar and the first section of the negative busbar are each oriented perpendicular or at least substantially perpendicular to a main extension plane of the printed circuit board, e.g. at an angle of 45° to 135°. The printed circuit board is expediently plate-shaped or flat. In particular, a main extension plane of the individual semiconductor switching elements is also oriented in each case parallel to the main extension plane of the first section of the busbars.

According to an embodiment, the half-bridge switch arrangement also has an output phase busbar, to which a second terminal of the first semiconductor switching elements, in particular a source terminal, and a first terminal of the second semiconductor switching elements, in particular a drain terminal, are electrically connected. The output phase busbar is arranged on a side of the printed circuit board facing away from the positive busbar and the negative busbar. The output phase busbar is suitably electrically connected to the printed circuit board. The output phase busbar is in particular plate-shaped or flat. The main extension planes of the printed circuit board and the output phase busbar are conveniently oriented parallel or at least substantially parallel to each other. In particular, the arrangement comprising the positive busbar, the negative busbar and the heat sink is arranged on an upper side of the printed circuit board and the output phase busbar is arranged on a lower side of the printed circuit board. Alternatively, the output phase busbar can also be designed as a component, in particular as one or more layers, of the printed circuit board. If a thickness of (copper) layers in the printed circuit board is large enough, one or more of the printed circuit board layers can thus also be used as an output phase busbar, so that no additional, separate output phase busbar is provided.

According to an embodiment, the half-bridge switch arrangement further comprises an electrical output phase insulating layer, wherein the output phase busbar is electrically insulated from the printed circuit board by the electrical output phase insulating layer. In particular, this electrical output phase insulating layer is arranged between the output phase busbar and the printed circuit board. Advantageously, the electrical output phase insulating layer is plate-shaped or flat in relation to the output phase busbar and the printed circuit board, and the main planes of extension of the printed circuit board, the output phase busbar and the electrical output phase insulating layer are oriented at least substantially parallel to one another. The output phase insulating layer can be a heat conducting pad.

According to an embodiment, the positive busbar and the negative busbar are each L-shaped with two legs, with a second section adjoining the first section of the positive or negative busbar at right angles or at least substantially at right angles. L-shaped is to be understood in particular as meaning that the respective conductor rail has an L-shaped profile in cross-section, with the respective first section forming a first leg of this profile and the respective second section forming a second leg. In particular, the two second sections point away from each other or towards each other or are arranged one above the other in the direction perpendicular to the printed circuit board.

According to an embodiment, the positive busbar and the negative busbar are oriented with respect to each other in such a way that the respective second section of the positive busbar and the negative busbar each adjoin the respective first section on a side of the respective first section facing away from the heat sink. In particular, the respective second section extends from the respective first section away from the heat sink. The positive busbar, the heat sink and the negative busbar together thus form a T-shape in a cross-section. In particular, the shapes and sizes of the positive busbar and the negative busbar can be at least essentially identical and the two busbars can be arranged symmetrically relative to the heat sink.

According to an alternative embodiment, the respective second section of the positive busbar and the negative busbar each adjoin the respective first section on a side of the respective first section facing the heat sink. The second sections are thus arranged parallel to each other above the heat sink. In particular, the positive busbar, the heat sink and the negative busbar together thus form a cuboid shape in cross-section.

According to an embodiment, wherein the second section of the positive busbar and the second section of the negative busbar extend above the heat sink, the second section of one of the two busbars selected from the positive busbar and the negative busbar is arranged between the heat sink and the second section of the other of the two busbars. The two second sections are thus arranged parallel to each other above the heat sink. Conveniently, the two second sections can be electrically insulated from each other by an insulating layer.

According to an embodiment, the half-bridge switch arrangement further comprises a capacitor unit or capacitor bank, which in turn comprises at least one discrete capacitor element, in particular a plurality of parallel-connected, discrete capacitor elements. A first terminal of the capacitor unit is electrically connected to the positive busbar, in particular to the second section of the positive busbar, and a second terminal of the capacitor unit is electrically connected to the negative busbar, in particular to the second section of the negative busbar. The capacitor unit or its capacitor elements are in particular DC link capacitors. The design and shape of the busbars can be used to provide sufficient space for these DC link capacitors, which can reduce the inductance of the commutation loop. By placing the DC link capacitors as close as possible to the switching elements, inductance in particular can be reduced. Due to the short distances between the lines of the switching elements, the busbars and the capacitor unit, the commutation loop can be optimized. The positioning of the capacitor unit and its connection to the busbars is easy to implement during the manufacturing process. In particular, the distance between the DC link capacitors and the switching elements can be as symmetrical as possible. The capacitor unit can be effectively cooled by the heat sink. For example, the capacitor unit can be cuboid in shape and have, for example, a special cuboid capacitor element or a large number of discrete capacitor elements arranged in a cuboid housing.

According to an embodiment, the capacitor unit is arranged on the second section of the positive busbar and/or on the second section of the negative busbar. If the respective second section of the positive or negative busbar is connected to the respective first section on a side facing away from the heat sink and if the positive busbar, the negative busbar and the heat sink together form a T-shape in cross-section, the capacitor unit can be arranged in particular on the upper side of the second sections and the heat sink. If the second section of the positive and negative busbars run on top of each other above the heat sink, the capacitor unit can be arranged on the upper of the two second sections in particular. The first terminal of the capacitor unit is suitably electrically connected to the second section of the positive busbar and the second terminal of the capacitor unit is suitably electrically connected to the second section of the negative busbar.

According to an embodiment, wherein the second section of the positive busbar and the second section of the negative busbar extend above the heat sink and wherein the second section of one of the two busbars is arranged between the heat sink and the second section of the other of the two busbars, at least one channel, hole or bore is provided in the second section of the other of the two busbars (i.e. in the upper busbar), through which the terminal of the capacitor unit is guided which is electrically connected to the one of the two busbars (i.e. to the lower upper busbar). The corresponding terminal of the capacitor unit can be conveniently connected directly to the upper of the two busbars. If the capacitor unit cannot easily be connected directly to the lower of the two busbars, the channel can be provided in the upper busbar, through which the corresponding terminal of the capacitor unit can nevertheless be contacted with the lower busbar in a structurally simple manner.

According to an embodiment, the half-bridge switch arrangement further comprises at least one first switching element insulating layer and at least one second switching element insulating layer. A housing of the first semiconductor switching elements is electrically insulated from the positive busbar by the at least one first electrical switching element insulating layer, in particular in order to electrically insulate the respective source terminal of the first semiconductor switching elements from the positive busbar. Accordingly, a housing of the second semiconductor switching elements is electrically insulated from the negative busbar by the at least one second electrical switching element insulating layer, in particular in order to electrically insulate the respective drain terminal of the second semiconductor switching elements from the negative busbar. For example, a separate insulating layer can be provided for each switching element or a common insulating layer can be provided for several switching elements. In particular, the switching element insulating layers represent a thermal interface material (TIM) between the switching elements and the busbars and can usefully have a low thermal resistance or a high thermal conductivity. For example, the switching element insulating layers can each be designed as a ceramic layer with very low thermal resistance. These switching element insulating layers allow heat to be effectively transferred from the semiconductor switching elements to the busbars and dissipated from these to the heat sink. When switching elements are arranged directly on a printed circuit board in a conventional way, the thermal resistance of the printed circuit board and the thermal interface material is often not particularly low, so that the switching elements often cannot be kept below a desired temperature without further ado. In contrast, in the present switch arrangement, the junction temperature of the switching elements can be kept at a desired value even at high current and high switching frequencies.

According to an embodiment, the half-bridge switch arrangement further comprises a first electrical heat sink insulating layer and a second electrical heat sink insulating layer, wherein the positive busbar is electrically insulated from the heat sink by the first electrical heat sink insulating layer and wherein the negative busbar is electrically insulated from the heat sink by the second electrical heat sink insulating layer. In particular, these heat sink insulating layers are each arranged between the heat sink and the respective first section of the respective busbar.

According to an embodiment, the positive busbar and the negative busbar each have crenellated contacts, in particular at an end of the respective first section opposite the respective second section. These contacts are used to electrically and mechanically connect the busbar to the printed circuit board. The printed circuit board is suitably provided with corresponding openings, bores, holes or recesses to accommodate the contacts. Such crenellated contacts make it easy to contact the printed circuit board.

The half-bridge switch arrangement or a half-bridge power stage comprising the half-bridge switch arrangement can be used in particular in a power converter or power converter circuit, for example for alternating conversion between direct and alternating voltages. The half-bridge switch arrangement is particularly suitable for use in a vehicle, for example to convert a voltage between a DC on-board power supply and an electrical machine that can be operated with a multi-phase AC voltage. By connecting the semiconductor switching elements in parallel as high-side or low-side switches, the desired power or current levels can be achieved, particularly in high-power converters in the vehicle sector.

Further advantages and embodiments of the disclosure are shown in the description and the accompanying drawing.

The disclosure is illustrated schematically in the drawing by means of embodiment examples and is described below with reference to the drawing.

### BRIEF DESCRIPTION OF THE DRAWINGS

FIG. 1 schematically shows an embodiment of a half-bridge switch arrangement according to the disclosure as an electrical circuit diagram.

FIGS. 2a, b schematically shows an embodiment of a half-bridge switch arrangement according to the disclosure in perspective views.

FIG. 3 shows a schematic perspective view of an embodiment of a half-bridge switch arrangement according to the disclosure.

### DETAILED DESCRIPTION

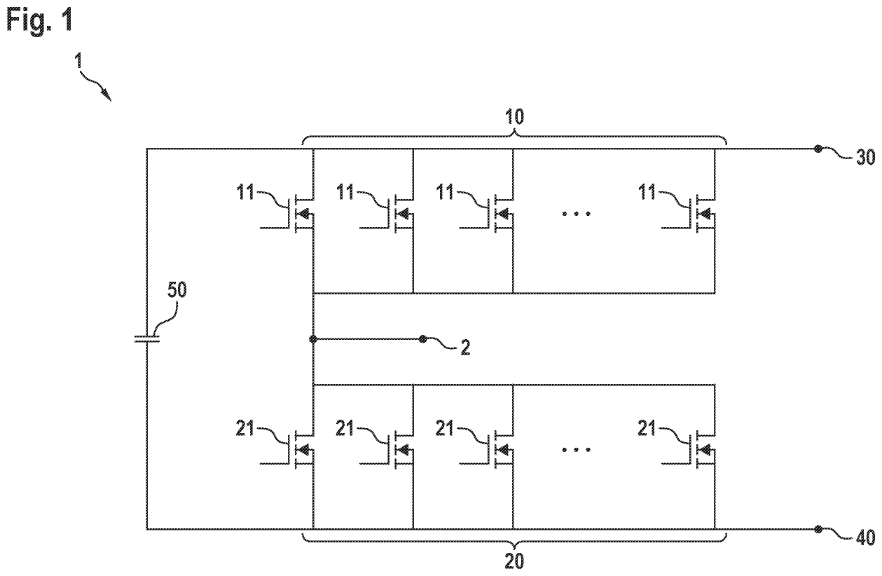

FIG. 1 schematically illustrates an embodiment of a half-bridge switch arrangement 1 according to the disclosure as an electrical circuit diagram.

The half-bridge switch arrangement 1 is provided for rectifying or alternating current between DC voltage terminals 30, 40 and an AC voltage terminal 2 and has a high-side switch 10 and a low-side switch 20. The high-side switch 10 has a plurality of discrete first semiconductor switching elements 11 connected in parallel, e.g. each in the form of a metal-oxide-semiconductor field-effect transistor (MOSFET) or an insulated-gate bipolar transistor (IGBT). Accordingly, the low-side switch 20 also has a plurality of parallel-connected, discrete second semiconductor switching elements 21, each of which can be designed, for example, as a MOSFET or IGBT. The number of semiconductor switching elements 11 or 21 can be selected in each case in order to achieve a desired power or a desired current.

The first semiconductor switching elements 11 of the high-side switch 10 are electrically connected to a positive busbar at their drain terminal (first terminal) and the second semiconductor switching elements 21 of the low-side switch 20 are electrically connected to a negative busbar at their source terminal (second terminal). Furthermore, an intermediate circuit capacitor 50 is provided, which is electrically connected to the positive busbar and to the negative busbar.

For example, the arrangement 1 can be used in a vehicle, wherein the DC voltage terminals 30, 40 can be connected, for example, to a DC on-board power supply and wherein a phase of an electrical machine can be connected to the AC voltage terminals 2, for example.

The electrical machine can be a multi-phase machine, e.g. with typically three or more phases. In particular, a half-bridge with high-side and low-side switches is provided for each of the phases, as shown in FIG. 1. Furthermore, in particular a control unit for controlling the individual switching elements 11, 21 can be provided. The control unit can control the gate terminals of the switching elements 11, 21 to rectify or alternate a current.

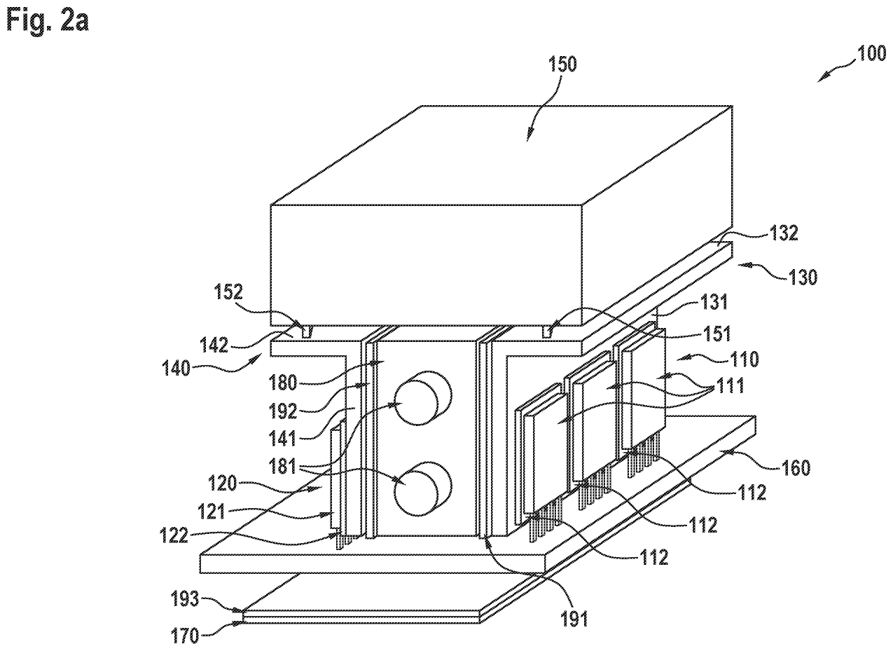

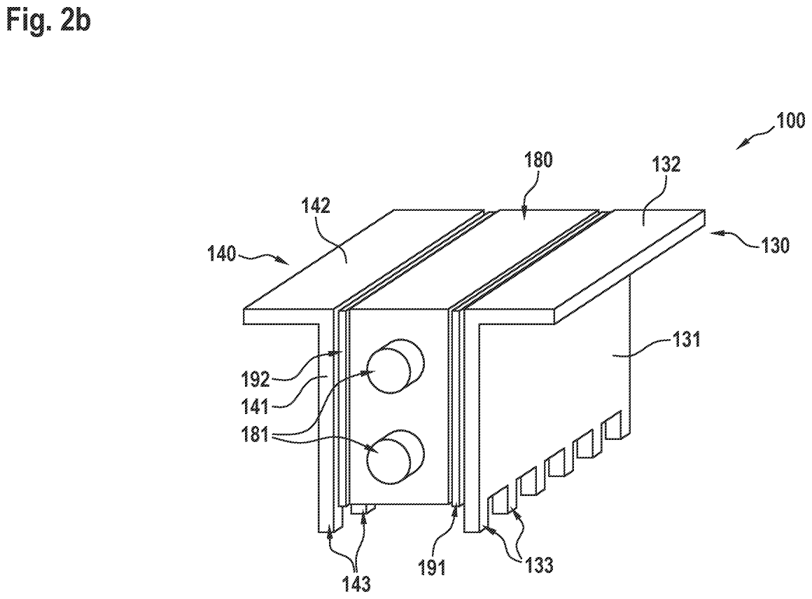

FIG. 2a shows a schematic perspective view of an embodiment of a half-bridge switch arrangement 100 according to the disclosure.

In accordance with the electrical circuit diagram shown in FIG. 1, the half-bridge switch arrangement 100 has a high-side switch 110 and a low-side switch 120, wherein the high-side switch 110 has a plurality of parallel-connected, discrete first semiconductor switching elements 111 and wherein the low-side switch 120 has a plurality of parallel-connected, discrete second semiconductor switching elements 121. The semiconductor switching elements 111 and 121 are each designed, for example, as a MOSFET or IGBT. In FIG. 2a, three first or second semiconductor switching elements 111 or 121 are provided as examples, but the number of semiconductor switching elements can also be larger or smaller, in particular depending on the desired power or desired current that is to flow through the semiconductor switching elements in total.

A positive busbar 130 is provided, to which the drain terminals (first terminal) of the first semiconductor switching elements 111 of the high-side switch 110 are electrically connected. A negative busbar 140 is provided, to which the source terminals (second terminal) of the second semiconductor switching elements 121 of the low-side switch 120 are electrically connected. An outer surface of the first semiconductor switching elements 111 is in thermal contact with a surface of the positive busbar 130. Correspondingly, an outer surface of the second semiconductor switching elements 121 is in thermal contact with a surface of the negative busbar 140. The electrical connection between the respective terminals of the semiconductor switching elements 111, 121 and the respective busbars 130, 140 can be established by means of a printed circuit board 160, which is explained further below.

A heat sink 180 is provided to cool the busbars 130, 140 and the semiconductor switching elements 111, 121. The heat sink 180 may be fluid cooled. Exemplary fluid terminals 181 for a cooling fluid are shown, but it is understood that the fluid terminals can also be designed in other ways. The fluid can, for example, be or comprise oil, cooling water, but also cooling air, i.e. air can also flow through it, for example.

In the shown embodiment, a first section 131 of the positive busbar 130 and a first section 141 of the negative busbar 140 are arranged parallel to each other and the heat sink 180 is arranged between these first sections 131, 141.

As shown in FIG. 2a, the positive busbar 130 can be L-shaped with two legs, with a second section 132 adjoining the first section 131 in this example at right angles, or at least essentially at right angles. Similarly, the negative busbar 140 is also L-shaped with two legs, with a second section 142 adjoining the first section 141 in this example at right angles, or at least essentially at right angles. The heat sink 180 can, for example, have a cuboid shape as shown in FIG. 2a, with adjacent side surfaces of the heat sink 180 abutting the first sections 131, 141.

As shown in FIG. 2a, the respective second section 132, 142 of the positive and negative busbars 130, 140 can each connect to this first section on a side of the respective first section 131, 141 facing away from the heat sink 180, so that the positive busbar 130, the heat sink 180 and the negative busbar 140 together form a T-shape in cross-section.

The first semiconductor switching elements 111 are arranged on a surface of the first section 131 of the positive busbar 130 facing away from the heat sink 180, in particular on a lower end of the first section 131 facing away from the second section 132, and are there in thermal contact with the positive busbar 130. Accordingly, the second semiconductor switching elements 121 are arranged on a surface of the first section 141 of the negative busbar 140 facing away from the heat sink 180, in particular at a lower end of this first section 141 facing away from the second section 142, and are in thermal contact there with the negative busbar 140.

The switch arrangement 100 also has a printed circuit board or control board 160, to which the positive busbar 130 and the negative busbar 140 are electrically connected. In the example shown, the two busbars 130, 140 are arranged on the printed circuit board 160 in such a way that the first section 131 of the positive busbar 130 and the first section 141 of the negative busbar 140 are each oriented vertically or at least substantially vertically to a main extension plane of the printed circuit board 160. In particular, the main extension planes of the semiconductor switching elements 111 and 121 are also parallel to the first sections and thus each oriented perpendicularly or at least substantially perpendicularly to the printed circuit board 160 and connected thereto.

An output phase busbar 170 is arranged on a side of the printed circuit board 160 facing away from the positive busbar 130 and the negative busbar 140. The source terminals (second terminal) of the first semiconductor switching elements 111 and the drain terminals (first terminal) of the second semiconductor switching elements 121 are electrically connected to the output phase busbar 170. The output phase busbar 170 is plate-shaped and the main extension planes of the output phase busbar 170 and the printed circuit board 160 are oriented parallel or at least substantially parallel to each other. Alternatively, the output phase busbar can also be formed as a component of the printed circuit board, so that one or more layers of the printed circuit board can be used as an output phase busbar.

The individual terminals of the switching elements 111 and 121 can each be formed, for example, as pins or wires, whereby the electrical connection of the respective terminals to the corresponding busbar on the underside of the printed circuit board 160 can be made by corresponding contacting or connection.

The output phase busbar 170 is electrically insulated from the printed circuit board 160 by an electrical output phase insulating layer 193. Further, the positive bus bar 130 is electrically insulated from the heat sink 180 by a first electrical heat sink insulating layer 191 and the negative bus bar 140 is electrically insulated from the heat sink 180 by a second electrical heat sink insulating layer 192.

Furthermore, at least one first electrical switching element insulating layer 112 and at least one second electrical switching element insulating layer 122 are provided for electrical insulation. The housings of the first semiconductor switching elements 111, in particular their respective source terminals, are electrically insulated from the positive busbar 130 by the at least one first switching element insulating layer 112. Correspondingly, the housings of the second semiconductor switching elements 121, in particular their respective drain terminals, are electrically insulated from the negative busbar 140 by the at least one second switching element insulating layer 122. As shown in FIG. 2a, a separate electrical insulating layer 112 or 122 can be provided for each switching element 111 or 121.

Individual, some or all of the heat sink insulating layers 191, 192, the output phase insulating layer 193 and the switching element insulating layers 112, 122 may each have a low or the lowest possible thermal resistance, or a high or the highest possible thermal conductivity. For example, the thermal conductivity of the insulating layers can each be more than 1, 10 or 100 W/(m·K). In this way, waste heat from the individual semiconductor switching elements 111, 121 can be efficiently transferred to the respective busbar 130 or 140 and dissipated from these through the heat sink 180.

The switch arrangement 100 further comprises a capacitor unit or capacitor bank 150, in particular of cuboidal shape, which comprises a discrete capacitor element or a plurality of parallel-connected discrete capacitor elements as intermediate circuit capacitors. As shown in FIG. 2a, the capacitor unit 150 may be disposed on the second portions 132, 142 of the L-shaped bus bars 130, 141 and on the heat sink 180. A first terminal 151 of the capacitor unit 150 is electrically connected to the second section 132 of the positive busbar 130, and a second terminal 152 of the capacitor unit 150 is electrically connected to the second section 142 of the negative busbar 140. By placing the capacitor unit 150 at least partially on the heat sink 180, the capacitor unit can be effectively cooled by the heat sink. For example, a thermal interface material (TIM) may be provided between the heat sink 180 and the capacitor unit 150.

In cross-section, the leg of the L-shaped busbars 130, 140 forming the respective first section 131, 141 can each be longer than the respective leg forming the second section 132, 142. In this way, the largest possible cooling surface for the L-shaped busbars 130, 140 and the switching elements 111, 121 can be achieved and the horizontal expansion to accommodate the capacitor unit 150 can be kept to a minimum.

FIG. 2b shows a schematic perspective view of the arrangement comprising the positive busbar 130, the negative busbar 140, the heat sink 180 and the two heat sink insulating layers 191, 192. As shown in FIG. 2b, the two L-shaped busbars 130, 140 each have crenellated contacts 133 or 143 for connection to the printed circuit board 160 at an end of the respective first section 131 or 141 opposite the respective second section 132 or 142. The printed circuit board 160 can have corresponding openings for receiving these contacts 131 or 143, whereby the contacts 133 or 143 can be soldered to the printed circuit board 160.

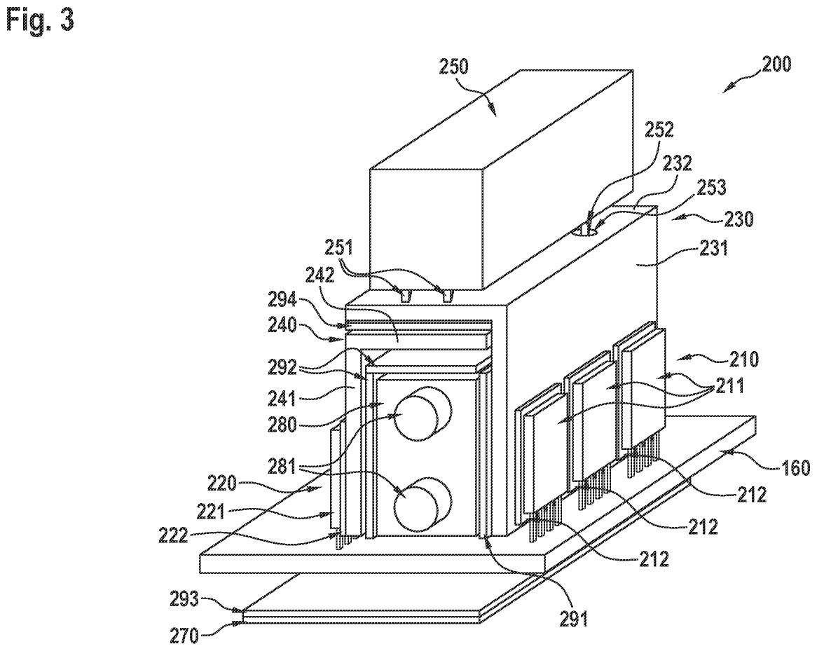

FIG. 3 schematically shows a further embodiment of a half-bridge switch arrangement 200 according to the disclosure. Identical or structurally identical elements of the switch arrangement 200 shown in FIG. 3 are each designated with a reference sign increased by the value “100” in comparison with the switch arrangement 100 shown in FIGS. 2a and 2b.

In contrast to the switch arrangement 100 of FIGS. 2a and 2b, the L-shaped busbars 230 and 240 in FIG. 3 are oriented in such a way that the respective second section 232 or 242 in each case adjoins the respective first section 231 or 241 on a side of the respective first section facing the heat sink 280. The second sections 232 and 242 are each arranged above the heat sink 280 and run parallel, with the second section 242 of the negative busbar 240 being arranged between the heat sink 280 and the second section 232 of the positive busbar 230. The L-shaped busbars 230 and 240 and the heat sink 280 together form a rectangle in cross-section or, extended, a cuboid shape. The two L-shaped busbars 230, 240 are electrically insulated from the heat sink 280 by a first and second electrical heat sink insulating layer 291 and 292, respectively. The second heat sink insulating layer 292 can also be L-shaped, for example. However, two second heat sink insulating layers may also be provided, wherein the first section 241 of the negative busbar 240 is insulated from the heat sink 280 by a first of these heat sink insulating layers and wherein the second section 242 of the negative busbar 240 is insulated from the heat sink 280 by a second of these heat sink insulating layers. Further, the two second portions 232, 242 of the L-shaped busbars 230, 240 are electrically insulated from each other by a further electrical insulating layer 294. It is also conceivable that the insulating layers 291, 294 are formed as a common, one-piece, L-shaped insulating layer, corresponding to the insulating layer 292. These insulating layers 291, 292 and 294 also expediently have a high thermal conductivity, as described above.

The capacitor unit 250 is arranged on the second section 232 of the positive busbar 230. A first terminal 251 of the capacitor unit 250 is directly connected to the second section 232 of the positive busbar 230. A channel 253 or a bore or a hole is provided in the second section 232 of the positive busbar 230, through which a second terminal 252 of the capacitor unit 230 is guided, which is electrically connected to the second section 242 of the negative busbars 240.

We claim:

1. A half-bridge switch arrangement (1, 100, 200), comprising:
a high-side switch (10, 110, 210) comprising a plurality of parallel-connected first semiconductor switching elements (11, 111, 211),
a low-side switch (20, 120, 220) comprising a plurality of parallel-connected second semiconductor switching elements (21, 121, 221),
a positive busbar (130, 230), to which a first terminal of each of the first semiconductor switching elements (11, 111, 211) of the high-side switch (10, 110, 210) is electrically connected,
a negative busbar (140, 240), to which a second terminal of each of the second semiconductor switching elements (21, 121, 221) of the low-side switch (20, 120, 220) is electrically connected, and
a heat sink (180, 280),
wherein the heat sink (180, 280) is arranged between a first section (131, 231) of the positive busbar (130, 230) and a first section (141, 241) of the negative busbar (140, 240),
wherein an outer surface of each of the first semiconductor switching elements (11, 111, 211) is in thermal contact with a surface of the first section (131, 231) of the positive busbar (130, 230) facing away from the heat sink (180, 280), and
wherein an outer surface of each of the second semiconductor switching elements (21, 121, 221) is in thermal contact with a surface of the first section (141, 241) of the negative busbar (140, 240) facing away from the heat sink (180, 280).

2. The half-bridge switch arrangement according to claim 1, further comprising a printed circuit board (160, 260),
wherein the positive busbar (130, 230) and the negative busbar (140, 240) are electrically connected to the printed circuit board (160, 260),
the positive busbar (130, 230) and the negative busbar (140, 240) being arranged on the printed circuit board (160, 260) in particular in such a way that the first section (131, 231) of the positive busbar (130, 230) and the first section (141, 241) of the negative busbar (140, 240) are each oriented perpendicularly or at least substantially perpendicularly to a main plane of extension of the printed circuit board (160, 260).

3. The half-bridge switch arrangement according to claim 2, further comprising an output phase busbar (170, 270), to which a second terminal of each of the first semiconductor switching elements (11, 111, 211) and a first terminal of each of the second semiconductor switching elements (21, 121, 221) are electrically connected,
wherein the output phase busbar (170, 270) is arranged on a side of the printed circuit board (160, 260) facing away from the positive busbar (130, 230) and the negative busbar (140, 240), or wherein the output phase busbar is formed as a component, in particular as one or more layers of the printed circuit board.

4. The half-bridge switch arrangement according to claim 3, further comprising an electrical output phase insulating layer (193, 293),
wherein the output phase busbar (170, 270) is insulated from the printed circuit board (160, 260) by the electrical output phase insulating layer (193, 293).

5. The half-bridge switch arrangement according to claim 1, wherein the positive busbar (130, 230) and the negative busbar (140, 240) are each L-shaped, wherein the first section (131, 231) of the positive busbar (130, 230) is adjoined at right angles or at least substantially at right angles by a second section (132, 232), and the first section (141, 241) of the negative busbar (140, 240) is adjoined at right angles or at least substantially at right angles by a second section (142, 242).

6. The half-bridge switch arrangement according to claim 5, wherein the positive busbar (130, 230) and the negative busbar (140, 240) are oriented with respect to one another in such a way that the respective second section (132, 142) of the positive busbar (130) and of the negative busbar (140) each adjoin the respective first section (131, 141) on a side of the respective first section (131, 141) facing away from the heat sink (180).

7. The half-bridge switch arrangement according to claim 5, wherein the positive busbar (130, 230) and the negative busbar (140, 240) are oriented with respect to one another in such a way that the respective second section (232, 242) of the positive busbar (230) and of the negative busbar (240) each adjoin the respective first section (131, 141) on a side of the respective first section (131, 141) facing the heat sink (180) and each extend above the heat sink (280).

8. The half-bridge switch arrangement according to claim 7, wherein the second portion (242) of one of the two bus bars (240) selected from the positive bus bar (230) and the negative bus bar (240) is disposed between the heat sink (280) and the second portion (232) of the other of the two bus bars (230).

9. The half-bridge switch arrangement according to claim 1, further comprising a capacitor unit (50, 150, 250) comprising at least one capacitor element, wherein a first terminal (151, 251) of the capacitor unit (150, 250) is electrically connected to the positive busbar (130, 230) and wherein a second terminal (152, 252) of the capacitor unit (150, 250) is electrically connected to the negative busbar (140, 240).

10. The half-bridge switch arrangement according to claim 9, wherein the positive busbar (130, 230) and the negative busbar (140, 240) are each L-shaped, wherein the first section (131, 231) of the positive busbar (130, 230) is adjoined at right angles or at least substantially at right angles by a second section (132, 232), and the first section (141, 241) of the negative busbar (140, 240) is adjoined at right angles or at least substantially at right angles by a second section (142, 242), wherein the capacitor unit (150, 250) is arranged on the second section (132, 232) of the positive busbar (130, 230) and/or on the second section (142, 242) of the negative busbar.

11. The half-bridge switch arrangement according to claim 10, wherein the positive busbar (130, 230) and the negative busbar (140, 240) are oriented with respect to one another in such a way that the respective second section (232, 242) of the positive busbar (230) and of the negative busbar (240) each adjoin the respective first section (131, 141) on a side of the respective first section (131, 141) facing the heat sink (180) and each extend above the heat sink (280), wherein the second portion (242) of one of the two bus bars (240) selected from the positive bus bar (230) and the negative bus bar (240) is disposed between the heat sink (280) and the second portion (232) of the other of the two bus bars (230), wherein the capacitor unit (250) is arranged on the second section (232) of the other of the two busbars (230), and at least one channel (253) is provided in the second section (232) of the other of the two busbars (230), through which channel the terminal (252) of the capacitor unit (250) is guided which is electrically connected to the one of the two busbars (240).

12. The half-bridge switch arrangement according to claim 1, further comprising at least a first electrical switching element insulating layer (112, 212) and at least a second electrical switching element insulating layer (122, 222),
wherein a housing and/or a second terminal of the first semiconductor switching elements (111, 211) are electrically insulated from the positive busbar (130, 230) by the at least one first electrical switching element insulating layer (112, 212), and
wherein a housing and/or a first terminal of the second semiconductor switching elements (121, 221) are electrically insulated from the negative busbar (140, 240) by the at least one second electrical switching element insulating layer (122, 222).

13. The half-bridge switch arrangement according to claim 1, further comprising a first electrical heat sink insulating layer (191, 291) and a second electrical heat sink insulating layer (192, 292),
wherein the positive busbar (130, 230) is electrically insulated from the heat sink (180, 280) by the first electrical heat sink insulating layer (191, 291), and
wherein the negative busbar (140, 240) is electrically insulated from the heat sink (180, 280) by the second electrical heat sink insulating layer (192, 292).

14. The half-bridge switch arrangement according to claim 2, wherein the positive busbar (130, 230) and the negative busbar (140, 240) each comprise crenellated contacts (133, 143) for attachment to the printed circuit board (160, 260).
